(19) United States
(12) Patent Application Publication
(10) Pub. No.: US 2020/0013586 A1
(43) Pub. Date: Jan. 9, 2020

(54) SEMICONDUCTOR PROCESSING APPARATUS FOR HIGH RF POWER PROCESS

(71) Applicant: Applied Materials, Inc., Santa Clara, CA (US)

(72) Inventors: Jun MA, Milpitas, CA (US); Jian LI, Fremont, CA (US); David H. QUACH, San Jose, CA (US); Amit Kumar BANSAL, Milpitas, CA (US); Juan Carlos ROCHA, San Carlos, CA (US)

(21) Appl. No.: 16/447,083

(22) Filed: Jun. 20, 2019

Related U.S. Application Data
(60) Provisional application No. 62/694,974, filed on Jul. 7, 2018.

(51) Int. Cl. H01J 37/32; H01L 21/67; C23C 16/458

(52) U.S. Cl. CPC H01J 37/32174; C23C 16/4586; H01L 21/67248; H01J 37/32724

(57) ABSTRACT

In some embodiments, the semiconductor process apparatus comprises a conductive support comprising mesh, a conductive shaft comprising a conductive rod, and a plurality of connection elements. The plurality of connection elements are coupled to the mesh in parallel and are connected to the rod at a single junction. The plurality of connection elements help spread RF current, reducing localized heating in the substrate, resulting in a more uniform film deposition. Additionally, using connection elements that are merged and coupled to a single RF rod allow for the rod to be made of materials that can conduct RF current at lower temperatures.

### CROSS-REFERENCE TO RELATED APPLICATIONS

This application claims priority to U.S. Provisional Patent Application No. 62/694,974, filed Jul. 7, 2018, which is herein incorporated by reference in its entirety.

### BACKGROUND

### Field

Embodiments described herein generally relate to semiconductor processing apparatuses that utilize high frequency power devices and, more particularly, to semiconductor processing apparatuses that utilize radio frequency (RF) power generation and/or delivery equipment.

### Description of the Related Art

Semiconductor processing apparatuses typically include a process chamber that is adapted to perform various deposition, etching, or thermal processing steps on a wafer, or substrate, that is supported within a processing region of the process chamber. As semiconductor devices formed on a wafer decrease in size, the need for thermal uniformity during deposition, etching, and/or thermal processing steps greatly increase. Small variations in temperature in the wafer during processing can affect the within-wafer (WIW) uniformity of these often temperature dependent processes performed on the wafer.

Typically, semiconductor processing apparatuses include a temperature controlled wafer support that is disposed in the processing region of a wafer processing chamber. The wafer support will include a temperature controlled support plate and a shaft that is coupled to the support plate. A wafer is placed on the support plate during processing in the process chamber. The shaft is typically mounted at the center of the support plate. Inside the support plate, there is conductive mesh made of materials such as molybdenum (Mo) that distribute RF energy to a processing region of a processing chamber. The conductive mesh is typically brazed to a metal containing connection element, which is typically connected to an RF match and RF generator or ground.

As RF power provided to the conductive mesh becomes high, so will the RF current passing through the connection elements. Each brazed joint that couples the metal containing connection element to the conductive mesh has a finite resistance, which will generate heat due to the RF current. As such, there is a sharp temperature increase, due to Joule heating, at the point where the conductive mesh is brazed to the metal containing connection element. The heat generated at the joint formed between the conductive mesh and the connection element will create a higher temperature region in the support plate near the joint which will result in a non-uniform temperature across the supporting surface of the support plate.

Additionally, the material selection of the RF connection element is limited due to the difficulty of brazing the RF connection element directly to the conductive mesh. Typically, the connection element is made of nickel (Ni) because it can be brazed to molybdenum (Mo), which is used to form the conductive mesh. However, Ni is not good at conducting RF current at low temperatures. Below its Curie point temperature, Ni is ferromagnetic and thus is a poor RF conductor, lowering the RF power delivery efficiency.

Accordingly, there is a need in the art to reduce the temperature variation across the support plate within a process chamber by improving the process of delivering RF power to a conductive electrode disposed within a substrate support in a process chamber. Additionally, there is a need for a way of improving the efficiency of delivering RF power to the conductive electrode.

### SUMMARY

One or more embodiments described herein provide a semiconductor processing apparatus with an RF mesh coupled to connection elements connected to a single RF rod.

In one embodiment, a semiconductor processing apparatus includes a thermally conductive substrate support comprising a mesh; a thermally conductive shaft comprising a conductive rod; and a connection assembly that is configured to electrically couple the conductive rod to the mesh, wherein connection assembly comprises a plurality of connection elements that each include a first end and a second end, wherein the first ends of each of the plurality of connection elements are coupled to a different portion of the conductive mesh; and a conductive plate, wherein the conductive plate is coupled to each of the second ends of the plurality of connection elements and a first end of the conductive rod.

In another embodiment, a semiconductor processing apparatus includes a thermally conductive substrate support comprising a mesh; a thermally conductive shaft comprising a conductive rod; and a connection assembly that is configured to electrically couple the conductive rod to the mesh, wherein the connection assembly comprises a plurality of connection elements that each include a first end and a second end, wherein the first ends of each of the plurality of connection elements are coupled to a different portion of the conductive mesh; and a conductive plate, wherein the conductive plate is coupled to each of the second ends of the plurality of connection elements and a first end of the conductive rod. The conductive rod comprises a first material having a first length and a second material having a second length, wherein the second material is disposed between and coupled to the first material and the conductive plate.

In yet another embodiment, a processing chamber includes a chamber body; a RF generator; and a thermally conductive substrate support comprising a mesh; a thermally conductive shaft comprising a conductive rod; and a connection assembly that is configured to electrically couple the conductive rod to the mesh, wherein the connection assembly comprises a plurality of connection elements that each include a first end and a second end, wherein the first ends of each of the plurality of connection elements are coupled to a different portion of the conductive mesh; and a conductive plate, wherein the conductive plate is coupled to each of the second ends of the plurality of connection elements and a first end of the conductive rod. The conductive rod comprises a first material having a first length and a second material having a second length, wherein the second material is disposed between and coupled to the first material and the conductive plate, wherein the second material is ferromagnetic at room temperature, and wherein the thermally conductive substrate support has a first operating temperature range that is greater than 360° C., and the temperature of all of the second material in the conductive rod is greater than the Curie temperature of the second material when the thermally conductive substrate support is maintained at a temperature within its first operating temperature range.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a side cross-sectional view of a processing chamber according to embodiments of the present disclosure;

FIG. 2A is a side cross-sectional view of the semiconductor processing apparatus of FIG. 1;

FIG. 2B is a schematic illustration of a temperature profile measured along a surface of a substrate in the prior art;

FIG. 2C is a schematic illustration of a temperature profile measured along a surface of a substrate according to embodiments of the present disclosure;

FIG. 2D is a perspective view of the semiconductor processing apparatus as shown in FIG. 1;

FIG. 3A is a side cross-sectional view of the semiconductor processing apparatus as shown in FIG. 1; and

FIG. 3B is a schematic illustration of a temperature profile measured along a surface of a conductive rod according to embodiments of the present disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

In the following description, numerous specific details are set forth to provide a more thorough understanding of the embodiments of the present disclosure. However, it will be apparent to one of skill in the art that one or more of the embodiments of the present disclosure may be practiced without one or more of these specific details. In other instances, well-known features have not been described in order to avoid obscuring one or more of the embodiments of the present disclosure.

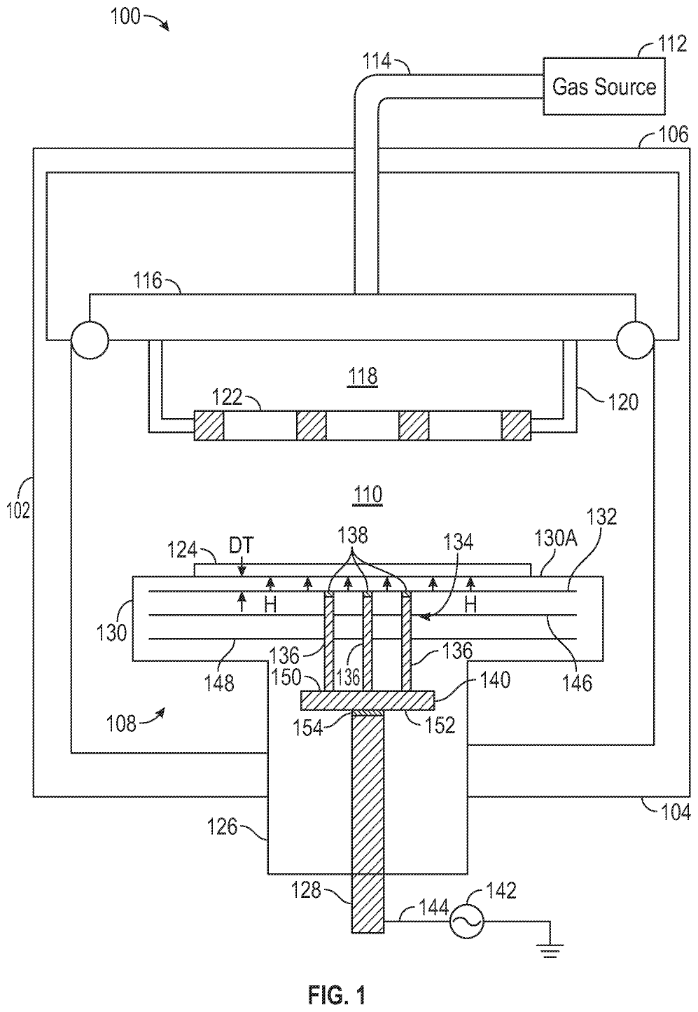

Embodiments described herein generally relate to semiconductor processing apparatuses that are adapted to perform high radio frequency (RF) power processes on a wafer disposed in a processing region of a semiconductor processing chamber. The semiconductor processing apparatus includes an RF powered mesh, which is disposed in a substrate supporting element, which is coupled to a connection assembly that is adapted to deliver RF energy to the RF powered mesh. In some embodiments, the connection assembly (i.e., connection assembly 134 in FIG. 1) includes a plurality of connection elements that are connected to the RF powered mesh at one end and a single RF rod at another end. The plurality of connection elements can be used to share and distribute the load created by the flow of a desired amount of RF current to the RF powered mesh. The plurality of connection elements configuration will thus help spread out the generated heat created by the delivery of the RF power to the RF powered mesh and reduce localized heating at the points where the connection elements are connected to the RF powered mesh. This results in a more uniform film deposition, etching, or thermal processing of the wafer.

Further, the connection assembly allows for the RF rod to be connected to the plurality of connection elements, instead of being directly connected to the mesh. As such, the material selection of the RF rod can include a broader range of materials that can more efficiently conduct the delivered RF current to the RF powered mesh. As the ability to conduct RF currents improves, RF efficiency also improves, which will result in reduced Joule heating, allow for smaller RF power delivery components and devices to be used during processing, and improved process control and efficiency.

FIG. 1 is a side cross-sectional view of a processing chamber according to embodiments of the present disclosure. By way of example, the embodiment of the processing chamber 100 in FIG. 1 is described in terms of a plasma-enhanced chemical vapor deposition (PECVD) system, but any other type of wafer processing chamber may be used, including other plasma deposition, plasma etching, or similar plasma processing chambers, without deviating from the basic scope of disclosed provided herein. The processing chamber 100 may include walls 102, a bottom 104, and a chamber lid 106 that together enclose a semiconductor processing apparatus 108 and a processing region 110. The semiconductor processing apparatus 108 is generally a substrate supporting element that may include a pedestal heater used for wafer processing. The pedestal heater may be formed from a dielectric material, such as a ceramic material (e.g., AIN, BN, or Al₂O₃ material). The walls 102 and bottom 104 may comprise an electrically and thermally conductive material, such as aluminum or stainless steel.

The processing chamber 100 may further include a gas source 112 and a radio frequency (RF) generator 142 that may be coupled to the semiconductor processing apparatus 108. The gas source 112 may be coupled to the processing chamber 100 via a gas tube 114 that passes through the chamber lid 106. The gas tube 114 may be coupled to a backing plate 116 to permit processing gas to pass through the backing plate 116 and enter a plenum 118 formed between the backing plate 116 and gas distribution showerhead 122. The gas distribution showerhead 122 may be held in place adjacent to the backing plate 116 by a suspension 120, so that the gas distribution showerhead 122, the backing plate 116, and the suspension 120 together form an assembly sometimes referred to as a showerhead assembly. During operation, processing gas introduced to the processing chamber 100 from the gas source 112 can fill the plenum 118 and pass through the gas distribution showerhead 122 to uniformly enter the processing region 110. In alternative embodiments, process gas may be introduced into the processing region 110 via inlets and/or nozzles (not shown) that are attached to one or more of the walls 102 in addition to or in lieu of the gas distribution showerhead 122.

The semiconductor processing apparatus 108 may comprise a thermally conductive substrate support 130 that includes an RF powered mesh, hereafter mesh 132, which is embedded inside the substrate support 130. The substrate support 130 also includes an electrically conductive rod 128 disposed within at least a portion of a conductive shaft 126 that is coupled to the substrate support 130. A substrate 124 (or wafer) may be positioned on top of the substrate support 130 during processing. In some embodiments, the RF generator 142 may be coupled to the conductive rod 128 via one or more transmission lines 144 (one shown). In at least one embodiment, the RF generator 142 may provide an RF current to the mesh 132 at a frequency of between about 200 kHz and about 81 MHz, such as between about 13.56 MHz and about 40 MHz. The power generated by the RF generator 142 acts to energize (or “excite”) the gas in the processing region 110 into a plasma state to, for example, form a layer on the surface of the substrate 124 during a plasma deposition process.

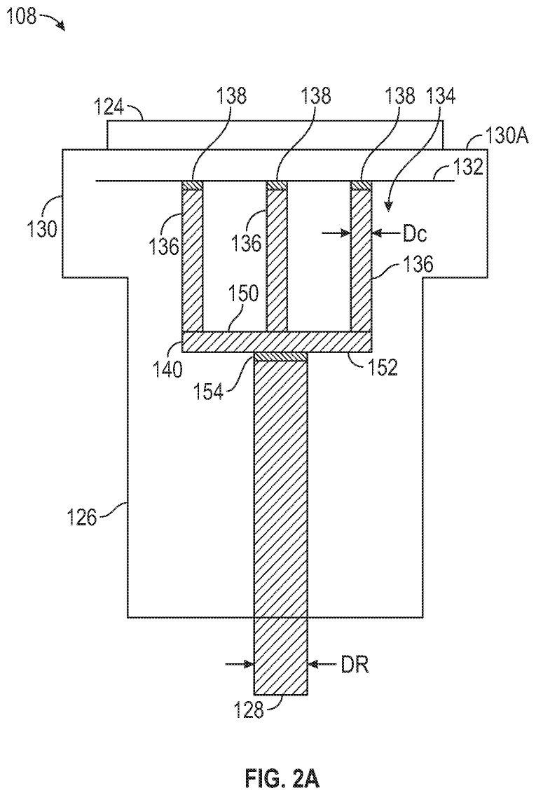

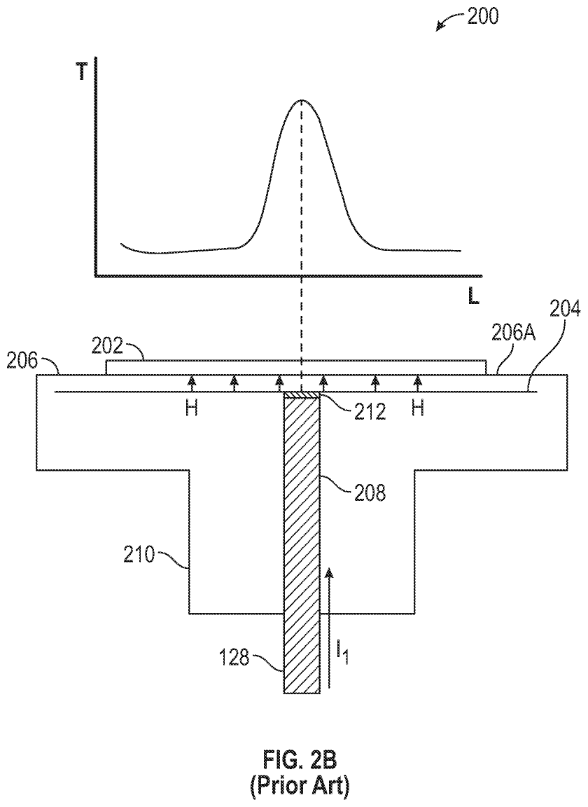

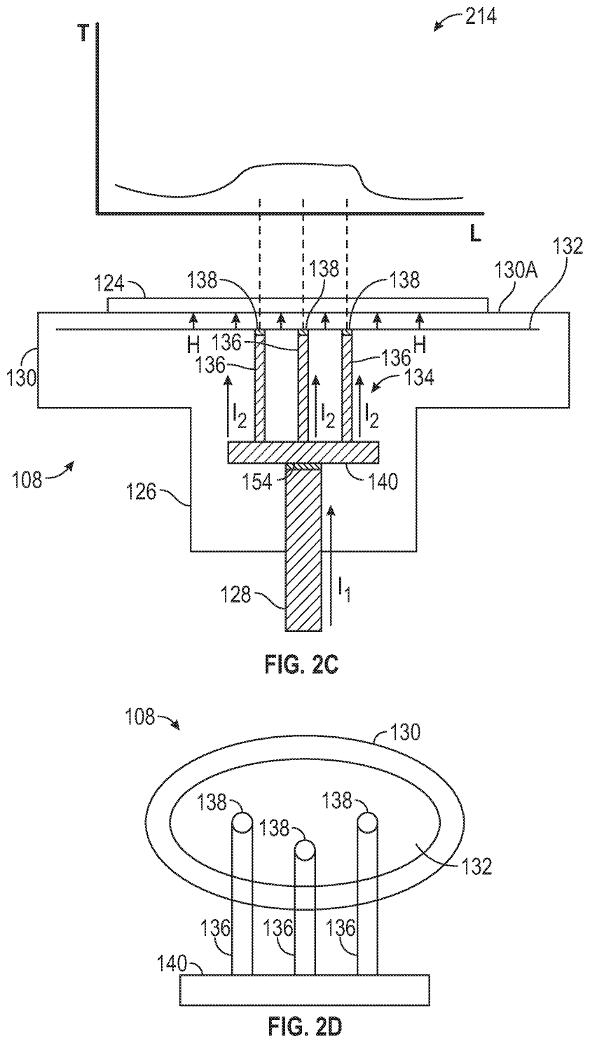

The conductive rod 128 is connected to the mesh 132 via a connection assembly 134. The connection assembly 134 may include a plurality of connection elements 136 (e.g., three are shown in FIGS. 1 and 2A), connection junctions 138, and a conductive plate 140. First ends of the connection elements 136 may each be physically and electrically coupled to the mesh 132 in parallel at the connection junctions 138. A first end of each of the connection elements 136 can be brazed to the mesh 132. Second ends of the connection elements 136 may each be coupled to a first side 150 of the conductive plate 140. The connection elements 136 can be brazed to the conductive plate 140, but can also be welded or coupled thereto by other joining methods. The conductive rod 128 may be connected to a second side 152 of the conductive plate 140 at a single connection junction 154. Likewise, the conductive rod 128 can be brazed to the conductive plate 140, but can also be coupled by other joining methods. As described in more detail in relation to FIGS. 2A-2C, the connection assembly 134 provides the advantage of dividing the RF current provided through the conductive rod 128 to each of the connection elements 136. This configuration acts to spread the RF current and thus reduces the Joule heating (e.g., I²R heating) at each of the connection junctions 138, resulting in a surface temperature of the substrate support 130 to be more uniform, which will translate into, for example, a more uniformly deposited film layer formed across the substrate 124. In one embodiment, the connection elements 136 are made of nickel (Ni), a Ni containing alloy, or other similar materials. The conductive plate 140 may be fabricated from any conductive, RF delivery, and process compatible material, such as nickel (Ni), molybdenum (Mo), or tungsten (W). The conductive plate 140 may be a circular shape, rectangular shape, triangular shape, or any other suitable shape that is sized to support the connection elements 136 and the conductive rod 128. The conductive plate 140 should have a suitable thickness (e.g., 0.5 mm-5 mm) to transmit the RF power provided from the conductive rod 128 to each of the connection elements 136.

Embedded within the substrate support 130 is the mesh 132, an optional biasing electrode 146, and a heating element 148. The biasing electrode 146, which is optionally formed within the substrate support 130, can act to separately provide an RF “bias” to the substrate 124 and processing region 110 through a separate RF connection (not shown). The heating element 148 may include one or more resistive heating elements that are configured to provide heat to the substrate 124 during processing by the delivery of AC power therethrough. The biasing electrode 146 and heating element 148 can be made of conductive materials such as Mo, W, or other similar materials.

The mesh 132 can also act as an electrostatic chucking electrode, which helps to provide a proper holding force to the substrate 124 against the supporting surface 130A of the substrate support 130 during processing. As noted above, the mesh 132 can be made of a refractory metal, such as molybdenum (Mo), tungsten (W), or other similar materials. In some embodiments, the mesh 132 is embedded at a distance DT (See FIG. 1) from the supporting surface 130A, on which the substrate 124 sits. The DT may be very small, such as less than 1 mm. Therefore, variations in temperature across the mesh 132 will greatly influence the variations in temperature of the substrate 124 disposed on the supporting surface 130A. The heat transferred from the mesh 132 to the supporting surface 130A is represented by the H arrows in FIG. 1.

Therefore, by dividing, distributing and spreading out the amount of RF current provided by each connection element 136 to the mesh 132, and thus minimizing the added temperature increase created at the connection element 136 to the connection junctions 138, will result in a more uniform temperature across the mesh 132 versus conventional connection techniques, which are discussed further below in conjunction with FIG. 2B. A more uniform temperature across the mesh 132, due to the use of the connection assembly 134 described herein, will create a more uniform temperature across the supporting surface 130A and substrate 124.

FIG. 2A is a side cross-sectional view of the semiconductor processing apparatus 108 of FIG. 1. As shown, the conductive rod 128 has a diameter, represented by DR, and each of the connection elements 136 has a diameter, represented by Dc. In some embodiments, each of the connection elements 136 has a smaller diameter than the conductive rod 128. One skilled in the art will appreciate that RF energy is primarily conducted through a surface region of a conductive element, and thus generally the majority of the current carrying area of an RF conductor will primarily be governed by the length of perimeter of RF conducting element. The majority of the current carrying area of an RF conductor is also reduced as the frequency of the delivered RF power increases, due to the decrease in the skin depth the delivered RF power is able to penetrate into the RF conductor as the RF power is delivered through the RF conductor. In one example, for a rod that has a circular cross-sectional shape, the RF current carrying area between its skin depth and surface (A_{ca}) will equal to the cross-section area (Aₒ) minus the current carrying area beyond its skin depth (Aₙₐ), where Aₒ equals π·Dₒ²/4 and Aₙₐ equals π·Dₙₐ²/4, where Dₒ is the outer diameter of the rod, and Dₙₐ is the diameter of the area below its skin depth (i.e., Dₙₐ=Dₒ−2·δ, where δ is the skin depth). Skin depth can be approximated by the equation δ=(ρ/(πfμrμo))^{0.5}, where ρ is the resistivity of the medium in Ω·m, f is the driven frequency in Hertz (Hz), μr is the relative permittivity of the material, and μo is the permittivity of free space. Skin depth refers to the point in which the current density reaches approximately 1/e (about 37%) of its value at the surface of the medium. Therefore, the majority of the current in a medium flows between the surface of the medium and its skin depth. In one example, the skin depth for a pure nickel material at 13.56 MHz will be approximately 1.46 micrometers (μm) and 0.85 μm at a frequency of 40 MHz. Therefore, in one example where a rod has an outer diameter Dₒ of 8 mm and is powered by an RF source driven at 13.56 MHz the current carrying area above its skin depth A_{ca} of the rod will only be about 3.8×10⁻² mm².

However, embodiments described in the disclosure generally will include a substrate support 130 configuration where the sum of the current carrying areas between the surfaces and skin depths of all of the connection elements 136 combined is larger than the current carrying area between the surface and skin depth of the conductive rod 128. This provides the advantage of creating a larger area to conduct the majority of RF energy through the interface between the connection elements 136 and the mesh 132, which will reduce the heat generated at the connection junctions 138 and also within the connection elements 136 versus a conventional single rod connection configuration shown in FIG. 2B, due to Joule heating. For example, when the DR of the conductive rod 128 is 6 mm (D_{R}=Dₒ according to the equations explained above), using the skin depth value of approximately 1.46 μm, Dₙₐ is approximately 5.997 mm (i.e., Dₙₐ=6 mm−2(0.00146 mm)). This leads to an A_{ca} of approximately 2.8×10⁻² mm² (i.e., A_{ca}=π(6 mm)²/4)−(π(5.997 mm)²/4) for the conductive rod 128, which is referred to A_{ca1} below. Comparatively, when the D_{c} of each connection element 136 is 3 mm (i.e., D_{c}=Dₒ), using the skin depth value of approximately 1.46 μm, Dₙₐ is approximately 2.997 mm (i.e., Dₙₐ=3 mm−2(0.00146 mm)). This leads to an A_{ca} of approximately 1.4×10⁻² mm² (i.e., A_{ca}=π(3 mm)²/4)−(π(2.997 mm)²/4) for each connection element 136, which is referred to A_{ca2} below. Thus, for a connection assembly that include three connection elements 136, the ratio of the total RF conductive area of the connection elements 136 to the RF conductive area of the conductive rod 128 (i.e., 3×A_{ca2}/A_{ca1}) will be about 1.5. Therefore, because the sum of the current carrying area between the surface and skin depth of each of the connection elements 136 is greater than the conductive rod 128, there is less Joule heating at each of the connection junctions 138 than at the single rod connection configuration shown in FIG. 2B.

The connection element configurations disclosed herein also provides an advantage over conventional designs since the smaller diameter connection elements have a smaller cross-sectional area and thus a smaller contact area at each of the connection junctions 138. The smaller cross-sectional area of the connection elements 136 will reduce the ability of each of the connection elements 136 to thermally conduct any heat generated in the connection elements 136 due to the delivery of the RF power therethrough. The reduced ability to conduct heat will also spread the heat more uniformly within the substrate support 130, helping to create a more uniform temperature distribution across the supporting surface 130A and substrate 124. Following the prior example above, where the DR of the conductive rod 128 is equal to 6 mm and the Dc of the mesh 132 is equal to 3 mm, for a three connection element 136 conductive assembly configuration, the ratio of the thermal conduction areas of the three connection elements 136 to conductive rod 128 area will be about 0.75.

In an effort to illustrate the effect of using the conductive assembly configurations disclosed herein, FIG. 2B is provided as a schematic illustration of a temperature profile formed across a substrate supporting surface 206A and a substrate 202 of a conventional substrate support 206 in the prior art, and FIG. 2C is provided as a schematic illustration of the temperature profile formed across the supporting surface 130A and the substrate 124 according to one or more embodiments of the present disclosure. As shown in FIG. 2B, a RF current is transferred through the prior art conductive rod 208. This RF current is represented by the value 1i. The prior art conductive rod 208 is disposed within the prior art conductive shaft 210 and is connected directly to the prior art mesh 204 at a single prior art junction 212. Therefore, the current flows entirely from the prior art conductive rod 208 to the single prior art junction 212. Conductive rods have a finite electrical impedance, which will generate heat due to the delivery of the RF current through the prior art conductive rod 208. As such, there is sharp increase in heat provided to the prior art connection junction 212 due to the reduced surface area that is able to conduct the RF power. As the heat flows upward through the prior art conductive substrate support 206 to the substrate 202, as shown by the H arrows, the temperature at the location of the substrate 202 above the prior art junction 212 spikes in the center region as shown by the graph 200, resulting in a non-uniform film layer.

Contrarily, as shown in FIG. 2C, the present disclosure provides the advantage of spreading the current I₁ generated through the conductive rod 128 into each of the connection elements 136. The current through each of the connection elements 136 is represented by I₂. In some embodiments, the current I₂ through each of the connection elements 136 can be equal. Therefore, in at least one embodiment, the connection elements 136 can comprise three elements (shown here). However, the connection elements 136 can comprise any number of multiple elements, including four or more. The current I₂ through the connection elements 136 can be at least three times less than the current I₁ through the conductive rod 128. Accordingly, current I₂ flows into the connection junctions 138 at a lower magnitude and at multiple distributed out points across the mesh 132, helping spread the amount of heat generated across the substrate 124, creating much less of a heat increase at any one point, as shown by the graph 214. This acts to improve the uniformity in the film layer. The spread of the connection junctions 138 across the mesh 132 of the substrate support 130 is best shown in FIG. 2D, which provides a perspective view of one embodiment the semiconductor processing apparatus 108. As shown, each of the connection junctions 138 can be spread relatively far apart from each other, widely distributing the current and the generated heat across the supporting surface 130A, resulting in a uniform heat spread across the substrate 124.

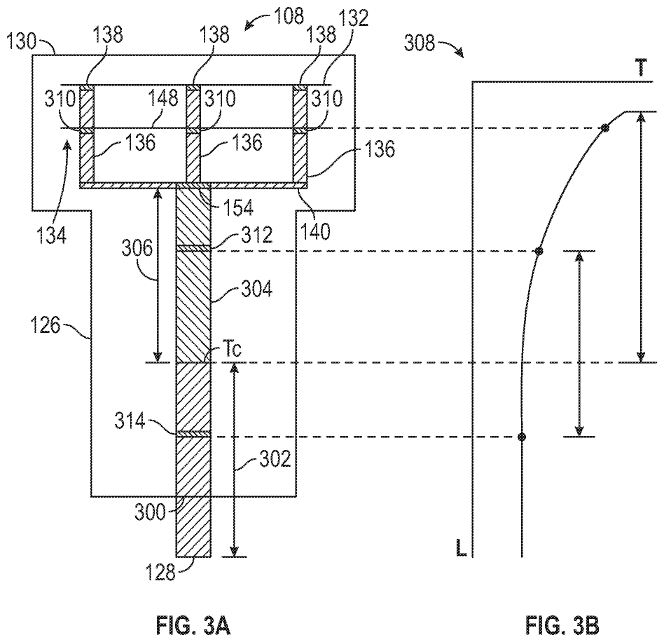

FIG. 3A is a sectional view of the connection assembly 134 as shown in FIG. 1, and FIG. 3B is a schematic illustration of the temperature along the conductive rod 128 according to embodiments of the present disclosure. The conductive rod 128 can comprise two or more serially connected materials, and thus form a composite conductive rod structure. In one embodiment, the conductive rod 128 includes a first material 300 having a first length 302 and a second material 304 having a second length 306. The first material 300 can be positioned within the substrate support 130 so that the temperature that is experienced along the first length, during normal processing, is at temperatures below its Curie temperature, and the temperature that is experienced along the second length 306 of the second material, during normal processing, is at temperatures above its Curie temperature. As shown in FIG. 3A, the second material 304 is disposed between the connection assembly 134 and the first material 300. The temperature of the conductive rod 128 matches the Curie temperature of the second material 304 at a point represented by T_{C} in FIG. 3A. The graph 308 in FIG. 3B shows how temperature changes throughout the length of the conductive rod 128. Some materials lose their magnetic properties above their Curie point temperature, and thus changing the material from ferromagnetic to paramagnetic.

As shown by the graph 308, during the normal operation of the substrate support 130 the temperature is generally at its highest close to the heating elements 148, while the temperature generally decreases as it extends away from the heating elements 148. For example, at first points 310, which corresponds to the temperature in the connection elements 136 near the heating elements 148, the temperature is high, such as, for example, a temperature of 350-900° C. Further away from the heating elements 148 at a second point 312, the temperature drops to a value much less than the values at the first points 310. The temperature at the second point 312 will depend on its distance from the heating elements 148, thermal conductivity of the conductive rod material, and the thermal environment surrounding the second point on the conductive rod 128. Even further away from the heating elements 148 at a third point 314, also corresponding to a temperature in the conductive rod 128, the temperature drops even further.

In some embodiments, the second material 304 reaches a temperature above its Curie point (T_{C}), and thus all regions of the second material 304 that are above the Curie point changes from ferromagnetic to paramagnetic. Ferromagnetic materials are poor RF conductors, and thus reduce RF efficiency. Therefore, in some embodiments, portions of the conductive rod 128 that are at a temperature that would be below the Curie point of a second material 304, it is preferable to replace or use a first material 300 that is non-ferromagnetic or has an even lower Curie point, and thus is a better a RF conductor at lower temperatures than the second material 304. In one embodiment, the second material 304 is a material that is paramagnetic above its Curie temperature, such as Ni (e.g., Curie temperature=627° K. (354° C.)). The first material 300 can be a material that is non-ferromagnetic, such as Ti. In some embodiments, it is desirable to design the conductive rod 128 of the substrate support 130 so that the temperature of all points along the second material 304 within a composite conductive rod 128, and including the junction between the first material 300 and the second material 304, is above the Curie point of the second material 304 when the substrate support 130 is operated in its normal operating range. In one example, the normal operating range of the substrate support 130 is between 350-900° C., and thus the temperature across the conductive rod 128 is between the substrate support's temperature set point and room temperature (e.g., 25° C.). In one example, the normal operating range of the substrate support 130 is greater than 350° C., such as greater than 360° C., or greater than 400° C., or greater than 450° C., or even greater than 500° C. Other similar materials with similar properties may be used, and such embodiments should not be construed as limiting. Using such materials at these lengths along the conductive rod 128 improves RF efficiency and reduces power loss, providing the advantages of improving the deposition and throughput.

While the foregoing is directed to embodiments of the present disclosure, other and further embodiments of the disclosure may be devised without departing from the basic scope thereof, and the scope thereof is determined by the claims that follow.

We claim:

1. A semiconductor processing apparatus, comprising:
a thermally conductive substrate support comprising a mesh;
a thermally conductive shaft comprising a conductive rod; and
a connection assembly that is configured to electrically couple the conductive rod to the mesh, wherein the connection assembly comprises:
a plurality of connection elements that each include a first end and a second end, wherein the first ends of each of the plurality of connection elements are coupled to a different portion of the conductive mesh; and
a conductive plate, wherein the conductive plate is coupled to each of the second ends of the plurality of connection elements and a first end of the conductive rod.

2. The semiconductor processing apparatus of claim 1, wherein a sum of an electrical conduction area of each of the plurality of connection elements is at least greater than an electrical conduction area of the conductive rod, wherein the electrical conduction area in each of the plurality of connection elements and in the conductive rod is determined based on a delivery of an RF frequency current from a power source.

3. The semiconductor processing apparatus of claim 1, further comprising a RF generator that is coupled to a second end of the conductive rod.

4. The semiconductor processing apparatus of claim 3, wherein a current generated by the RF generator is spread equally through each of the plurality of connection elements.

5. The semiconductor processing apparatus of claim 4, wherein the current through each of the plurality of connection elements is at least three times less than the current generated by the RF generator.

6. The semiconductor processing apparatus of claim 1, wherein the plurality of connection elements comprise at least three connection elements.

7. The semiconductor processing apparatus of claim 1, wherein the plurality of connection elements are made of Ni.

8. A semiconductor processing apparatus, comprising:
a thermally conductive substrate support comprising a mesh;
a thermally conductive shaft comprising a conductive rod; and
a connection assembly that is configured to electrically couple the conductive rod to the mesh, wherein the connection assembly comprises:
a plurality of connection elements that each include a first end and a second end, wherein the first ends of each of the plurality of connection elements are coupled to a different portion of the conductive mesh; and
a conductive plate, wherein the conductive plate is coupled to each of the second ends of the plurality of connection elements and a first end of the conductive rod.
wherein the conductive rod comprises a first material having a first length and a second material having a second length, wherein the second material is disposed between and coupled to the first material and the conductive plate.

9. The semiconductor processing apparatus of claim 8, wherein the second material is ferromagnetic at room temperature.

10. The semiconductor processing apparatus of claim 8, wherein the first material is Ti and the second material is Ni.

11. The semiconductor processing apparatus of claim 8, wherein the thermally conductive substrate support has a first operating temperature range that is greater than 360° C., and the temperature of all of the second material in the conductive rod is greater than the Curie temperature of the second material when the thermally conductive substrate support is maintained at a temperature within its first operating temperature range.

12. The semiconductor processing apparatus of claim 8, wherein the plurality of connection elements are made of Ni.

13. The semiconductor processing apparatus of claim 8, wherein a sum of an electrical conduction area of each of the plurality of connection elements is at least greater than an electrical conduction area of the conductive rod, wherein the electrical conduction area in each of the plurality of connection elements and in the conductive rod is determined based on a delivery of an RF frequency current from a power source.

14. The semiconductor processing apparatus of claim 8, further comprising a RF generator coupled to the semiconductor processing apparatus, wherein current generated by the RF generator is spread equally through each of the plurality of connection elements.

15. A processing chamber, comprising:
a chamber body;
a RF generator; and
a thermally conductive substrate support comprising a mesh;
a thermally conductive shaft comprising a conductive rod; and
a connection assembly that is configured to electrically couple the conductive rod to the mesh, wherein the connection assembly comprises:
a plurality of connection elements that each include a first end and a second end, wherein the first ends of each of the plurality of connection elements are coupled to a different portion of the conductive mesh; and
a conductive plate, wherein the conductive plate is coupled to each of the second ends of the plurality of connection elements and a first end of the conductive rod.
wherein the conductive rod comprises a first material having a first length and a second material having a second length, wherein the second material is disposed between and coupled to the first material and the conductive plate,
wherein the second material is ferromagnetic at room temperature, and
wherein the thermally conductive substrate support has a first operating temperature range that is greater than 360° C., and the temperature of all of the second material in the conductive rod is greater than the Curie temperature of the second material when the thermally conductive substrate support is maintained at a temperature within its first operating temperature range.

16. The semiconductor processing apparatus of claim 15, wherein a sum of an electrical conduction area of each of the plurality of connection elements is at least greater than an electrical conduction area of the conductive rod, wherein the electrical conduction area in each of the plurality of connection elements and in the conductive rod is determined based on a delivery of an RF frequency current from a power source.

17. The semiconductor processing apparatus of claim 15, wherein current generated by the RF generator is spread equally through each of the plurality connection elements.

18. The semiconductor processing apparatus of claim 17, wherein the current through each of the plurality of connection elements is at least three times less than the current generated by the RF generator.

19. The semiconductor processing apparatus of claim 15, wherein the first material is Ti and the second material is Ni.

20. The semiconductor processing apparatus of claim 15, wherein the plurality of connection elements comprise three connection elements.
